(19) United States
(12) Patent Application Publication
(10) Pub. No.: US 2003/0205268 A1
(43) Pub. Date: Nov. 6, 2003

(54) Photoelectric conversion device and photo cell

(75) Inventors: Yoshisada Nakamura, Kanagawa (JP); Yoshio Tadakuma, Kanagawa (JP); Yoshikatsu Kagawa, Kanagawa (JP)

Correspondence Address: SUGHRUE, MION, ZINN, MACPEAK & SEAS, PLLC, 2100 Pennsylvania Avenue, N.W., Washington, DC, 20037, US

(73) Assignee: FUJI PHOTO FILM CO., LTD.

(21) Appl. No.: 10/434,206

(22) Filed: May 9, 2003

Related U.S. Application Data
(62) Division of application No. 09/879,150, filed on Jun. 13, 2001.

(30) Foreign Application Priority Data
Jun. 13, 2000 (JP) P. 2000-177211

(51) Int. Cl. H01L 25/00

(52) U.S. Cl. 136/250; 438/63

(57) ABSTRACT

A photoelectric conversion device comprising a particulate semiconductor layer, wherein the particulate semiconductor layer is prepared by a method comprising a step of irradiating semiconductor particles with electromagnetic wave or a step of heating semiconductor particles at a temperature of 50° C. or higher and lower than 350° C. under a pressure of 0.05 MPa or lower.

### CROSS-REFERENCE RELATED TO APPLICATION

This is a divisional of application Ser. No. 09/879,150 filed Jun. 13, 2001; the disclosure of which is incorporated herein by reference.

### FIELD OF THE INVENTION

This invention relates to a photoelectric conversion device comprising a particulate semiconductor and a photo cell comprising the photoelectric conversion device. More particularly, it relates to a dye-sensitized photoelectric conversion device and a photo cell using the same.

### BACKGROUND OF THE INVENTION

In the field of photovoltaic power generation, the focus of researches for practical application has been chiefly put on improvements on monocrystalline silicon solar cells, polycrystalline silicon solar cells, amorphous silicon solar cells, and compound solar cells using cadmium telluride, copper indium selenide, etc. The state-of-the-art solar cells have achieved a power generation efficiency of about 10%. It is required for spread of solar cells in the future to overcome such problems as a high energy cost for preparing materials, which imposes a high load on the environment, and a long energy payback time. Although many solar cells using organic materials have been proposed aiming at an increase of working area and a reduction of cost, they have a conversion efficiency as low as 1% and poor durability.

Under these circumstances, Nature, vol. 353, pp. 737-740 (1991) and U.S. Pat. No. 4,927,721 disclose a photoelectric conversion device using dye-sensitized semiconductor particles, a photo cell comprising the device, and materials and techniques for producing them. The proposed cell is a wet type solar cell comprising, as a work electrode, a porous thin film of titanium dioxide spectrally sensitized by a ruthenium complex. A primary advantage of this system is that such an inexpensive oxide semiconductor as titanium dioxide can be used without being highly purified so that a photoelectric conversion device can be supplied at a competitive price. A secondary advantage is that the sensitizing dye used shows a broad absorption spectrum so that substantially the whole range of visible light can be converted to electricity.

However, the above-described dye-sensitized photoelectric conversion devices have limited application in view of the increasing use of photo cells because the porous titanium dioxide thin film is formed by firing at a high temperature exceeding 400° C., which prohibits use of flexible polymer substrates. In addition, using such a high temperature means consumption of a large amount of energy and involves not inconsiderable influences on the environment.

### SUMMARY OF THE INVENTION

An object of the present invention is to provide a photoelectric conversion device and a photo cell which have a high energy conversion efficiency.

Another object of the invention is to provide a photoelectric conversion device and a photocell which can comprise a flexible substrate.

Still another object of the invention is to provide a photoelectric conversion device and a photocell which are produced with reduced energy and therefore achieve improved energy recovery efficiency.

The objects of the invention are accomplished by:

(1) A photoelectric conversion device comprising a particulate semiconductor layer, wherein the particulate semiconductor layer is prepared by a method comprising a step of irradiating semiconductor particles and a precursor of semiconductor particles with ultraviolet light having a wavelength of 400 nm or shorter at which the semiconductor particles have an absorption.

(2) A photoelectric conversion device comprising a particulate semiconductor layer, wherein the particulate semiconductor layer is prepared by a method comprising steps of heating semiconductor particles at a temperature of 50° C. or higher and lower than 350° C. and irradiating the semiconductor particles with ultraviolet light having a wavelength of 400 nm or shorter at which the semiconductor particles have an absorption.

(3) A photoelectric conversion device comprising a particulate semiconductor layer, wherein the particulate semiconductor layer is prepared by a method comprising a step of heating semiconductor particles at a temperature of 50° C. or higher and lower than 350° C. under a pressure of 0.05 MPa or lower.

(4) A photoelectric conversion device comprising a particulate semiconductor layer, wherein the particulate semiconductor layer is prepared by a method comprising a step of irradiating semiconductor particles with microwaves.

(5) A photoelectric conversion device comprising a particulate semiconductor layer, wherein the particulate semiconductor layer is prepared by a method comprising a step of irradiating semiconductor particles with infrared light having a wavelength at which water molecules have an absorption.

(6) The photoelectric conversion device as set forth in (1) to (5) above, wherein the semiconductor particles constituting the particulate semiconductor layer comprise those having a particle size of 10 nm or greater and those having a particle size smaller than 10 nm.

(7) The photoelectric conversion device as set forth in (2) to (6) above, wherein the particulate semiconductor layer is prepared in the presence of a precursor of semiconductor particles.

(8) The photoelectric conversion device as set forth in (1) or (7) above, wherein the precursor of semiconductor particles is an alkoxide compound of a metal constituting the semiconductor, a halogen compound of the metal, or a compound obtained by completely or partially hydrolyzing a compound of the metal having a hydrolyzable group and completely or partially polymerizing the hydrolysis product.

(9) The photoelectric conversion device as set forth in (1) to (8) above, wherein the particulate semiconductor layer is sensitized with a dye.

(10) The photoelectric conversion device as set forth in (1) to (9) above, wherein the semiconductor particles constituting the particulate semiconductor layer are particles of titanium oxide, zinc oxide, tin oxide, tungsten oxide, niobium oxide, iron oxide, an alkaline earth metal titanate, an alkali metal titanate or a composite thereof.

(11) The photoelectric conversion device as set forth in (1) to (10) above, wherein the particulate semiconductor layer is provided on a substrate made of a polymer.

(12) A photo cell comprising the photoelectric conversion device as set forth in (1) to (11) above.

### BRIEF DESCRIPTION OF THE DRAWINGS

FIGS. 1 through 9 each present a partial cross section showing a preferred structure of the photoelectric conversion device according to the present invention.

FIG. 10 schematically illustrates the way of superposing electrodes in Examples.

### DETAILED DESCRIPTION OF THE INVENTION

[I] Photoelectric Conversion Device

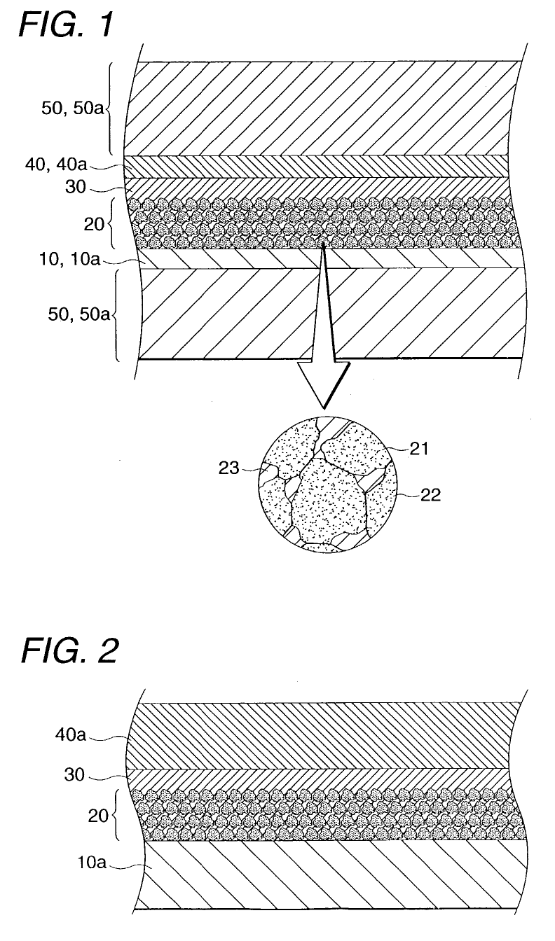

The photoelectric conversion device according to the present invention preferably comprises an electrically conductive layer 10, a photosensitive layer 20, a charge transporting layer 30, and an electrically conductive layer 40 as a counterelectrode (hereinafter referred to as a counterelectrode conductive layer 40) in this order. The photosensitive layer 20 is made up of semiconductor particles 21 which are sensitized with a dye 22 and a charge transporting material 23 penetrating into the gaps among the semiconductor particles 21. The semiconductor particles 21 are in contact with one another and connected to one another to form a porous film. The charge transporting material 23 is the same as the material forming the charge transporting layer 30. A base 50 may be provided on the conductive layer 10 and/or the counterelectrode conductive layer 40 to impart strength to the device. In what follows, the layer composed of the conductive layer 10 and the base 50, which can be provided optionally, will be referred to as a conductive substrate, and the layer composed of the counterelectrode conductive layer 40 and the base 50, which can be provided optionally, will be referred to as a counterelectrode. In FIG. 1, the conducive layer 10, the counterelectrode conductive layer 40, and the bases 50 may be a transparent conductive layer 10a, a transparent counterelectrode conductive layer 40a, and transparent bases 50a, respectively. The photoelectric conversion device connected to an external load to do an electric work (photovoltaic power generation) is a photo cell. The photoelectric conversion device connected to an external load for sensing optical information is an optical sensor. Of photo cells those in which the charge transporting material 23 mainly comprises ion transporting material are called photo-electrochemical cells, and those chiefly designed for power generation with sunlight are named solar cells.

Light having entered the photosensitive layer 20 comprising the dye 22-sensitized semiconductor particles 21 excites the dye 22. The excited dye has high energy electrons, which are handed over from the dye to the conduction band of the semiconductor particles 21 and diffused to reach the conductive layer 10. In this situation, the molecules of the dye 22 are in an oxidized state as a result of the electron migration. In a photo cell, the electrons in the conductive layer 10 work in an external circuit and return to the oxidized dye 22 through the counterelectrode conductive layer 40 and the charge transporting layer 30, thereby regenerating the dye 22. The photosensitive layer 20 acts as a negative electrode (optical anode) of the cell. The components constituting the individual layers may be diffused and mixed mutually at the boundaries, for example, the boundary between the conductive layer 10 and the photosensitive layer 20, the boundary between the photosensitive layer 20 and the charge transporting layer 30, and the boundary between the charge transporting layer 30 and the counterelectrode conductive layer 40.

(A) Conductive Substrate

The conductive substrate is (1) a single conductive layer or (2) a combination of a conductive layer and a base. In the case (1), a conductive material having sufficient strength and securing sufficient tight sealing properties, such as metal, is used. In the case (2), a base having a conductive layer containing a conducting agent on the photosensitive layer side is used. Preferred conducting agents include metals (e.g., platinum, gold, silver, copper, zinc, titanium, aluminum, and indium), carbon, and electrically conductive metal oxides (e.g., indium tin oxide and F-doped or Sb-doped tin oxide). The conductive layer preferably has a thickness of about 0.02 to 10 μm.

The conductive substrate preferably has as low a surface resistivity as possible. A desirable surface resistivity is 50 Ω/square or smaller, particularly 20 Ω/square or smaller.

Where light is incident upon the conductive substrate side of the photoelectric conversion device, it is preferred that the conductive substrate be substantially transparent to light. The term “substantially transparent” is intended to mean that the light transmission is at least 10%, preferably 50% or more, still preferably 80% or more.

A preferred transparent conductive substrate is a transparent base of glass, plastics, etc. having formed thereon a transparent conductive layer comprising a conductive metal oxide by coating or vacuum deposition or a like technique. A preferred transparent conductive layer includes F- or Sb-doped tin dioxide and indium-tin oxide (ITO). The transparent base includes soda-lime glass, which is advantageous for cost and strength, alkali-free glass, which has no fear of alkali dissolution, and transparent polymer films. Useful transparent polymers include tetraacetylcellulose (TAC), polyethylene terephthalate (PET), polyethylene naphthalate (PEN), syndiotactic polystyrene (SPS), polyphenylene sulfide (PPS), polycarbonate (PC), polyacrylate (PAr), polysulfone (PSF), polyester sulfone (PES), polyether-imide (PEI), cyclic polyolefins, and brominated phenoxy resins. To secure sufficient transparency, the amount of the conductive metal oxide to be applied is preferably 0.01 to 100 g per m² of the glass or plastic base.

In order to decrease the resistance of the transparent conductive substrate, it is preferred to use metal leads, which are preferably made of platinum, gold, titanium, aluminum, copper, silver, etc. The metal lead is preferably formed on the transparent base by vacuum evaporation, sputtering or a like deposition technique, on which a transparent conductive layer of tin oxide or ITO is provided. Reduction in incident light quantity due to the metal leads is preferably within 10%, still preferably 1 to 5%.

(B) Photosensitive Layer

In the photosensitive layer, the semiconductor acts as a photoreceptor that absorbs light to separate charges to generate electrons and positive holes. In the dye-sensitized semiconductor, the tasks of light absorption and generation of electrons or holes are chiefly performed by the dye, and the semiconductor plays a role in accepting and transmitting the electrons (or positive holes). It is preferred for the semiconductor used in the invention to be n-type one in which conduction band electrons serve as a carrier to afford an anode current under light irradiation.

(1) Semiconductor

The semiconductor which can be used in the photosensitive layer includes element semiconductors, e.g., Si or Ge, and compound semiconductors, such as III-V element-containing compound semiconductors, metal chalcogenides (e.g., oxides, sulfides, and selenides), and perovskite semiconductors.

The metal chalcogenides preferably include an oxide of titanium, tin, zinc, iron, tungsten, zirconium, hafnium, strontium, indium, cerium, yttrium, lanthanum, vanadium, niobium or tantalum; a sulfide of cadmium, zinc, lead, silver, antimony or bismuth; a selenide of cadmium or lead; and cadmium telluride. The perovskite semiconductors include strontium titanate, calcium titanate, sodium titanate, barium titanate, and potassium niobate. Other compound semiconductors include a phosphide of zinc, gallium, indium or cadmium, gallium arsenide, copper indium selenide, and copper indium sulfide.

Examples of semiconductors preferred for use in the photosensitive layer include Si, TiO₂, SnO₂, Fe₂O₃, WO₃, ZnO, Nb₂O₅, CdS, ZnS, PbS, Bi₂S₃, CdSe, CdTe, GaP, InP, GaAs, CuInS₂, and CuInSe₂. Still preferred are TiO₂, ZnO, SnO₂, Fe₂O₃, WO₃, Nb₂O₅, an alkaline earth metal titanate, and an alkali metal titanate. TiO₂, ZnO, SnO₂ and Nb₂O₅ are particularly preferred. TiO₂ is the most preferred. These semiconductors can be used either individually or in the form of a composite thereof, such as a mixture, a mixed crystal or a solid solution.

The semiconductor may be single crystalline or polycrystalline. While a single crystal is preferred for conversion efficiency, a polycrystalline semiconductor is preferred from the standpoint of production cost, abundance of raw materials, energy payback time, and the like. A porous semiconductor layer made of fine particles is particularly preferred.

The semiconductor particles, which generally have a particle size on the order of nanometers to microns, preferably have an average primary particle size of 5 to 200 nm, particularly 8 to 100 nm, in terms of a projected area, diameter. It is preferred for the semiconductor particles to comprise those having a particle size of 10 nm or greater and those having a particle size of 10 nm or smaller. The semiconductor particles in a dispersed state (secondary particles) preferably have an average particle size of 0.01 to 30 μm.

Semiconductor particles of two or more kinds having different size distributions can be used as a mixture. In this case, the average size of smaller particles is preferably 10 nm or smaller. For the purpose of scattering incident light to improve the rate of capturing light, large semiconductor particles about 300 nm in size may be used in combination.

The particulate semiconductor is preferably prepared by a sol-gel method described, e.g., in Sumio Sakubana, Sol-gel-hono kagaku, Agune Shofusha (1988) and Gijutsu Joho Kyokai, Sol-gel-ho niyoru hakumaku coating gijutsu (1995), and a gel-sol method described in Tadao Sugimoto, Materia, vol. 35, No. 9, pp. 1012-1018, “Shin goseiho gel-sol-ho niyoru tanbunsan ryushino goseito size keitai seigyo” (1996). The method for preparing an oxide developed by Degussa AG which comprises pyrogenically hydrolyzing a metal chloride in an oxyhydrogen flame is also preferred.

For preparation of titanium oxide particles, a sulfuric acid method and a chlorine method described in Manabu Seino, Sanka titan busseito ohyogijutu, Gihodo (1997) are also employable for preference in addition to the above-described sol-gel method, gel-sol method and pyrogenic flame hydrolysis. Of the available sol-gel methods for preparing titanium oxide particles, particularly preferred are the method described in Barbe, et al, Journal of American Ceramic Society, vol. 80, No. 12, pp. 3157-3171 (1997) and the method described in Burnside, et al., Chemical Materials, vol. 10, No. 9, pp. 2419-2425.

Titanium oxide may take an anatase form or a rutile form or a mixed form thereof. Anatase titanium oxide is preferred in the present invention. When titanium oxide is a mixture of anatase and rutile, the anatase proportion is preferably more than 50%, particularly 80% or more. The anatase content is obtained from the intensity ratio of the diffraction peaks assigned to anatase and rutile in X-ray diffractometry.

(2) Formation of Particulate Semiconductor Layer

The particulate semiconductor layer is formed on the conductive substrate by, for example, a method comprising coating the conductive substrate with a dispersion or colloidal solution of the semiconductor particles or the aforementioned sol-gel method, and the like. Film formation in a wet system is relatively advantageous, taking into consideration suitability to large-scale production of a photoelectric conversion device, controllability of liquid physical properties, and adaptability to various conductive substrates. Film formation in a wet system is typically carried out by application methods or printing methods.

Useful dispersing media include water and various organic solvents, such as methanol, ethanol, isopropyl alcohol, dichloromethane, acetone, acetonitrile, and ethyl acetate. In preparing a dispersion, a polymer (e.g., polyethylene glycol), a surface active agent, an acid, a chelating agent, and the like may be added as a dispersant if desired. In particular, use of polyethylene glycol with an appropriately controlled molecular weight is effective for modifying the viscosity of the dispersion, forming a hardly peelable film or controlling the porosity of the semiconductor layer.

The semiconductor layer does not need to be a single layer. Two or more layers different in particle size of semiconductor particles, in kind of semiconductors or in composition as for the binder or additives can be provided. In case where single operation of application is insufficient for giving a desired thickness, multilayer coating is effective. Extrusion coating or slide hopper coating is fit for multilayer coating. Multilayer coating can be carried out simultaneously or by successively repeating a coating operation several times or more than ten times. Screen printing is also preferably applicable to successive multilayer coating.

In general, as the thickness of the particulate semiconductor layer (i.e., the photosensitive layer) increases, the amount of the dye held per unit projected area increases to show an increased rate of capturing light, but the distance of diffusion of generated electrons also increases, which results in an increased loss due to recoupling of charges. Accordingly, there is a favorable thickness range for the particulate semiconductor layer, which is typically from 0.1 to 100 μm. Where the device is used as a solar cell, a more favorable thickness is 1 to 30 μm, particularly 2 to 25 μm. The coating weight of the semiconductor particles is preferably 0.5 to 100 g/m², still preferably 3 to 50 g/m².

When a particulate semiconductor is used as an element constituting a photoelectric conversion device, the function as a particulate semiconductor layer has been drawn by firing. That is, on heating an applied particulate semiconductor in high temperature, the particles are partly fused together to manifest electrical conductivity, and unnecessary matter on the particle surface is removed to activate the semiconductor. With the semiconductor particles thus activated, adsorption and binding of a sensitizing dye, which is applied in the subsequent step, are accelerated to increase photoelectron injection efficiency from the sensitizing dye into the particles. For that purpose, the firing should be conducted at a high temperature dependent on the semiconductor composition, which is 400° C. or higher. In case of titanium dioxide, for example, the firing temperature is preferably 450° C. or higher.

The present invention is characterized in that the above-mentioned state that has been to be resulted from “firing” is reached not by high-temperature heating but by a method including one or more than one of the following steps.

(1) The semiconductor particles are heated at a temperature of 50° C. or higher and lower than 350° C.

(2) The semiconductor particles are irradiated with ultraviolet light having a wavelength of 400 nm or shorter at which the semiconductor particles have an absorption.

(3) The semiconductor particles are irradiated with microwaves.

(4) The semiconductor particles are irradiated with infrared light having an absorption at which water molecules have an absorption.

(5) The semiconductor particles are exposed to a vacuum of 0.05 MPa or lower.

(6) The semiconductor particles are exposed in an ozone atmosphere.

(7) The semiconductor particles are placed under an oxidative or reducing condition.

(8) The semiconductor particles are placed in a high electric field.

(9) The semiconductor particles are placed in a high magnetic field.

(10) A high current is passed through the semiconductor particles.

(11) The semiconductor particles are combined with a precursor of semiconductor particles.

In order to fuse the particles together, it is necessary to supply energy to move a substance to contact points among the particles by surface diffusion, grain boundary diffusion or the like to form necks. It is effective for this purpose to supply thermal energy (step (1)) or electromagnetic energy by electromagnetic wave (steps (2), (3), (4), (8) or (9)) or to apply a high current to cause the semiconductor itself or the boundaries to generate resistance heat (step (10)).

In order to remove unnecessary matter from the surface to activate the particles, it is effective to apply heat to cause the unnecessary matter to evaporate or decompose (step (1)), to draw vacuum to accelerate the evaporation (step (5)), or to induce a chemical reaction to cause decomposition (steps (6) and (7)). Irradiation is also an effective means for those particles which have a function as a photo-catalyst generating a powerful oxidizing or reducing species on irradiation, such as TiO₂ particles. Ultraviolet irradiation according to step (2) is particularly effective for TiO₂ particles. Presence of a precursor of semiconductor particles (step (11)) under each of the above-described conditions is effective in reducing the energy required for a substance to diffuse or to be supplied and preferred for forming a particulate semiconductor layer having a photoelectric function at a lower temperature. In carrying out the heating step (1), although a higher heating temperature is more effective for the semiconductor particles to fuse together, a lower temperature is preferred with heat resistance of a polymer substrate taken into consideration. From these viewpoints, the upper limit of the heating temperature is preferably 300° C., still preferably 250° C., and the lower limit is preferably 80° C., still preferably 100° C.

It is preferred to combine one of the steps for fusing the particles (steps (1) to (4) and (8) to (10)) and one of the steps for removing unnecessary matter and activation (steps (1) and (5) to (7)). It is still preferred that these combinations be further combined with step (11). It is also effective to combine two or more of the steps for fusing the particles (steps (1) to (4) and (8) to (10)) and/or two or more of the steps for removing unnecessary matter and activation (steps (1) and (5) to (7)). Specific examples of preferred combinations of steps include, but are not limited to, (1)+(2), (1)+(3), (1)+(4), (1)+(5), (1)+(2)+(5), (4)+(5), (2)+(4)+(5), (3)+(5), (1)+(2)+(6), (4)+(6), (3)+(7), (1)+(3)+(7), (1)+(8), (1)+(2)+(8), (1)+(2)+(8)+(10), etc. It is also preferred for these combinations to be further combined with step (11).

The combined steps can be carried out either simultaneously or successively. For example, where steps (1) and (2) are combined, steps (1) and (2) can be performed simultaneously, or step (1) can be followed by step (2), or step (2) can be followed by step (1), or a concurrent combination of steps (1) and (2) is followed by step (1).

It should be noted that step (2) is liable to make the surface of the semiconductor particles, particularly titanium dioxide particles, excessively hydrophilic so that it is preferred to conduct step (2) in the final stage of semiconductor layer formation or otherwise, which depends on the purpose. It should also be noted that step (1), on the contrary, is apt to make the surface of the semiconductor particles, particularly titanium dioxide particles, hydrophobic so that it is advised that step (1) be performed in the final stage of semiconductor layer formation or otherwise, which depends on the purpose. For example, where a particulate semiconductor layer is formed by the combination of steps (1) and (2), which is followed by adsorption of a sensitizing dye, it is desirable that step (1) be preceded by step (2) or steps (1) and (2), which are carried out concurrently, be followed by step (1) because semiconductor particles with higher hydrophobic properties show higher adsorptivity for a sensitizing dye, particularly a hydrophobic dye.

The precursor of the semiconductor particles used in step (11) is not limited and includes any substance capable of being converted into semiconductor particles on heating. Precursors of metal oxide semiconductor particles include metal alkoxides, metal halides, and metallic compounds having a hydrolyzable group. The hydrolyzable group is a group displaceable with a proton or a hydroxyl group and preferably includes an acyloxy group, an alkoxycarbonyloxy group, and a carbamoyloxy group. Also included in the precursors are a partial or complete hydrolysis product of the above-described precursor metallic compound, a polymer of the hydrolysis product, and a mixture thereof. In particular, a mixture obtained by partially hydrolyzing a metal alkoxide or halide with an acid or an alkali and partially polymerizing the hydrolysis product is effective for its high reactivity. The acid for the hydrolysis preferably includes hydrochloric acid and nitric acid, with hydrochloric acid being particularly preferred.

The metal of the precursor and the main metal constituting the particulate semiconductor layer may be the same or different but are desirably the same. Where a different metal is used, a titanium compound or a silicon compound is advantageous for low-temperature reactivity in hydrolysis and polymerization. The above-recited precursors can be used either individually or as a combination of two or more thereof. The solid content of the precursor is 5/1000 to 1/5, preferably 1/100 to 1/10 based on the weight of the semiconductor particles. The term “the solid content of the precursor” as used herein means weight of solutes excluding solvent in a solution of the precursor in case of the precursor making solution composition.

For the purpose of increasing the surface area of the semiconductor particles and of increasing the purity in the vicinities of the semiconductor particles thereby to improve electron injection efficiency from the dye to the semiconductor particles, the particulate semiconductor layer having been treated by one or more of steps (1) to (11) can be subjected to chemical plating with a titanium tetrachloride aqueous solution or electrochemical plating with a titanium trichloride aqueous solution.

It is preferable for the particulate semiconductor layer to have a large surface area so that they may adsorb as large an amount of a dye as possible. The surface area of the semiconductor particles in the state applied to the conductive substrate is preferably 10 times or more, still preferably 100 times or more, the projected area. The practical upper limit of the surface area is, while not limited to, about 1000 times the projected area.

(3) Dye

The sensitizing dye which can be used in the photosensitive layer is not particularly limited. Any dye having an absorption in the visible region or the near infrared region and capable of sensitizing semiconductors can be used arbitrarily. Preferably included are organic metal complex dyes, methine dyes, porphyrin dyes, and phthalocyanine dyes. Two or more kinds of dyes can be used in combination so as to broaden the wavelength region of photoelectric conversion and to increase the conversion efficiency. The dyes to be combined and their ratio can be selected in conformity with the wavelength region and the intensity distribution of a light source to be used.

It is preferred for the dyes to have an appropriate interlocking group for linking to the surface of the semiconductor particles. Preferred interlocking groups include acidic groups, such as —COOH, —OH, —SO₃H, —P(O)(OH)₂ and —OP(O)(OH)₂, and chelating groups having pi conductivity, such as oxime, dioxime, hydroxyquinoline, salicylate and □-keto-enolate groups. Particularly preferred of them are —COOH, —P(O)(OH)₂, and —OP(O)(OH)₂. The interlocking group may be in the form of a salt with an alkali metal, etc. or an intramolecular salt. Where the methine chain of a polymethine dye has an acidic group as in the case where the methine chain forms a squarylium ring or a croconium ring, that moiety can serve as a interlocking group.

(a) Organic Metal Complex Dye

The metal complex dyes preferably include phthalocyanine dyes, porphyrin dyes and ruthenium complex dyes, with ruthenium complex dyes being particularly preferred. Useful ruthenium complex dyes are described, e.g., in U.S. Pat. Nos. 4,927,721, 4,684,537, 5,084,365, 5,350,644, 5,463,057, and 5,525,440, JP-A-7-249790, JP-W-10-504521, WO98/50393, and JP-A-12-26487. Those represented by formula (I) are particularly preferred.

(A₁)ₚRu(B-a)(B-b)(B-c) (I)

wherein A₁ represents a unidendate or bidentate ligand which is preferably selected from Cl, SCN, H₂O, Br, I, CN, NCO, SeCN, a β-diketonato, an oxalato, and a dithiocarbamic acid derivative; p represents an integer of 0 to 3; and B-a, B-b, and B-c each independently represent an organic ligand selected from B-1 to B-10 shown below.

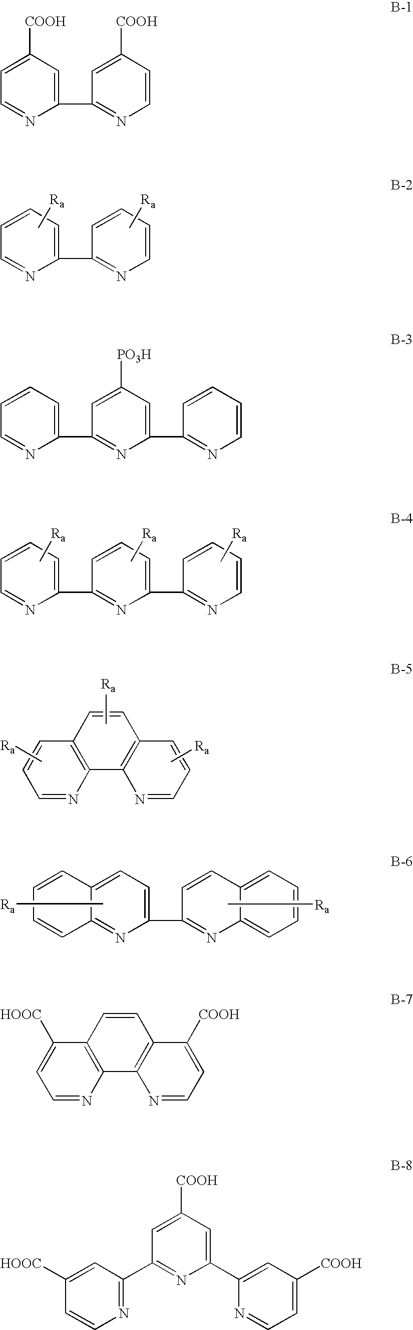

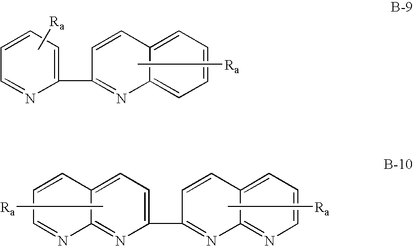

wherein Rₐ represents a hydrogen atom or a substitutent.

The substituent as Ra includes a halogen atom, a substituted or unsubstituted alkyl group having 1 to 12 carbon atoms, a substituted or unsubstituted aralkyl group having 7 to 12 carbon atoms, a substituted or unsubstituted aryl group having 6 to 12 carbon atoms, a carboxyl group, and a phosphoric acid group. The acid groups may be in a salt form. The alkyl group and the alkyl moiety of the aralkyl group may be either straight or branched, and the aryl group and the aryl moiety of the aralkyl group may be either monocyclic or polycyclic (condensed rings or independent rings). The organic ligands, B-a, B-b and B-c, may be the same or different.

Specific examples of preferred ruthenium complex dyes represented by formula (I) are tabulated below.

(A₁)ₚRu (B-a) (B-b) (B-c)

| No. | A₁ | p | B-a | B-b | B-c | Rₐ |
|---|---|---|---|---|---|---|
| R-1 | SCN | 2 | B-1 | B-1 | — | — |
| R-2 | CN | 2 | B-1 | B-1 | — | — |
| R-3 | C1 | 2 | B-1 | B-1 | — | — |
| R-4 | CN | 2 | B-7 | B-7 | — | — |
| R-5 | SCN | 2 | B-7 | B-7 | — | — |
| R-6 | SCN | 2 | B-1 | B-2 | — | H |
| R-7 | SCN | 1 | B-1 | B-3 | — | — |
| R-8 | C1 | 1 | B-1 | B-4 | — | H |
| R-9 | I | 2 | B-1 | B-5 | — | H |
| R-10 | SCN | 3 | B-8 | — | — | — |
| R-11 | CN | 3 | B-8 | — | — | — |
| R-12 | SCN | 1 | B-1 | B-2 | — | H |
| R-13 | — | 0 | B-1 | B-1 | B-1 | — |

Specific examples of other preferred metal complex dyes are shown below.

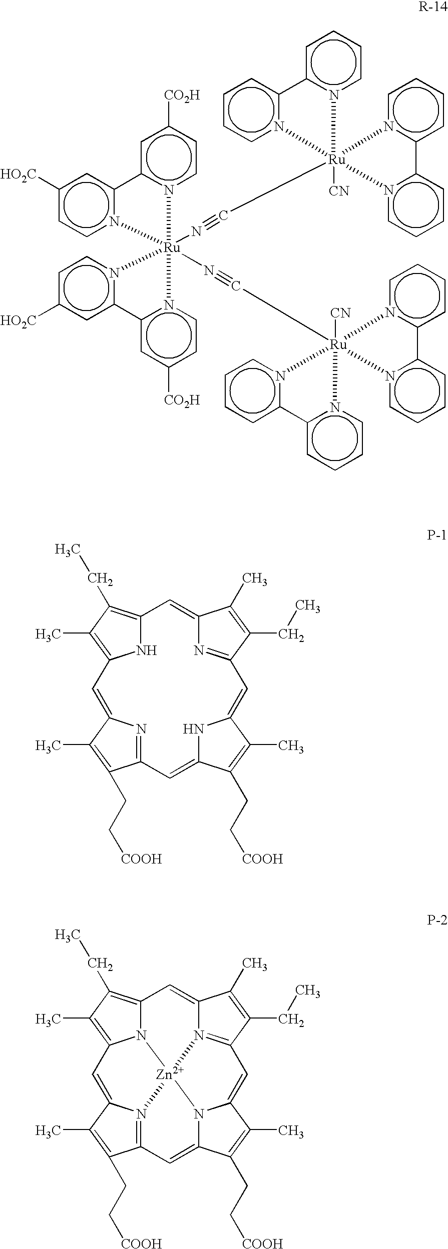

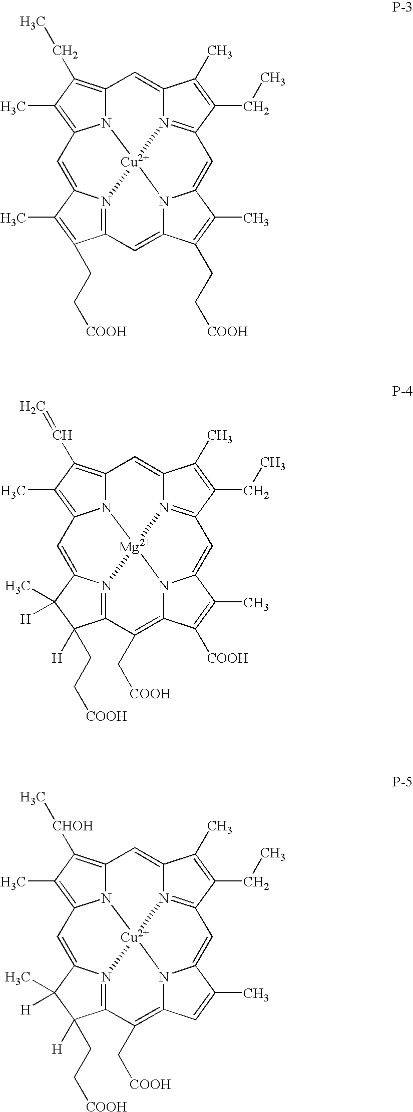

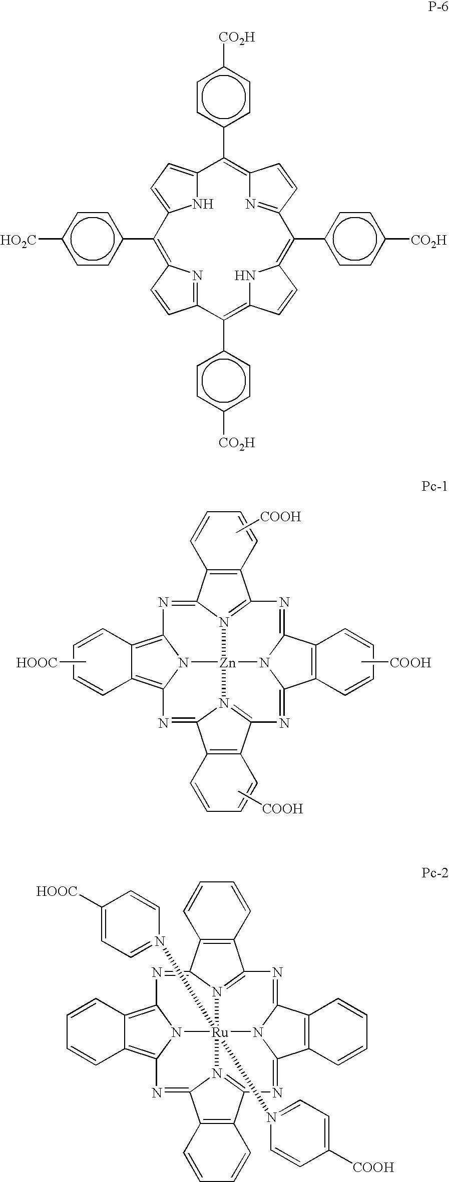

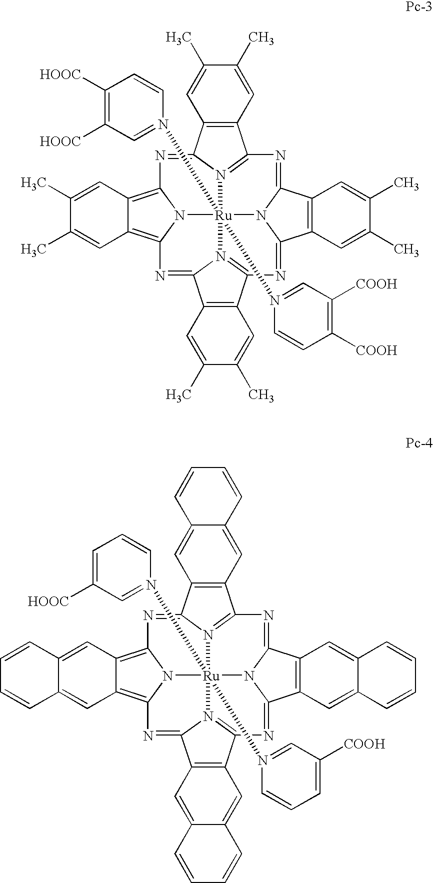

(b) Methine Dye

The methine dyes which can be used preferably include polymethine dyes, such as cyanine dyes, merocyanine dyes, and squarylium dyes. Examples of polymethine dyes that can be used preferably in the invention are described in JP-A-11-35836, JP-A-11-67285, JP-A-11-86916, JP-A-11-97725, JP-A-11-158395, JP-A-11-163378, JP-A-11-214730, JP-A-11-214731, JP-A-11-238905, EP 892411, EP 892411, and EP 911841.

(4) Dye Adsorption on Semiconductor Particles

Adsorption of the dye on semiconductor particles is effected by dipping a well-dried conductive substrate having a particulate semiconductor layer in a dye solution, which can be embodied by immersion, dip coating, roll coating, air knife coating, etc., or coating the semiconductor layer with a dye solution, which can be embodied by wire bar coating, slide hopper coating, extrusion coating, curtain coating, spin coating, spraying, and the like. In case of immersion, the dye adsorption may be either at room temperature or under reflux as taught in JP-A-7-249790.

The solvent of the dye solution includes alcohols (e.g., methanol, ethanol, t-butanol and benzyl alcohol), nitrites (e.g., acetonitrile, propionitrile and 3-methoxypropionitrile), nitromethane, halogenated hydrocarbons (e.g., dichloromethane, dichloroethane, chloroform, and chlorobenzene), ethers (e.g., diethyl ether and tetrahydrofuran), dimethyl sulfoxide, amides (e.g., N,N-dimethylformamide and N,N-dimethylacetamide), N-methylpyrrolidone, 1,3-dimethylimidazolidinone, 3-methyloxazolidinone, esters (e.g., ethyl acetate and butyl acetate), carbonic esters (e.g., diethyl carbonate, ethylene carbonate, and propylene carbonate), ketones (e.g., acetone, 2-butanone, and cyclohexanone), hydrocarbons (e.g., hexane, petroleum ether, benzene, and toluene), and mixtures thereof.

In order to obtain a sufficient sensitizing effect, the dyes are preferably adsorbed in a total amount of 0.01 to 100 mmol per m² of the conductive substrate and 0.01 to 100 mmol per gram of the semiconductor particles. With too small a total amount of the dyes, the sensitizing effect would be insufficient. If the dyes are used in too large a total amount, the non-adsorbed dyes will float only to lessen the sensitizing effect. It is preferable for increasing the dye adsorption that the semiconductor layer be subjected to heat treatment before dye adsorption. Where the heat treatment is conducted, it is preferred that the dye be quickly adsorbed into the heated semiconductor layer while it is between 40° C. and 80° C. so as to prevent water from being adsorbed to the semiconductor particles.

A colorless compound may be adsorbed together with the dye to lessen the interaction among dye molecules, such as association. Compounds having surface active characteristics and structure, such as carboxyl-containing steroid compounds (e.g., chenodeoxycholic acid) and sulfonic acid salts, are effective for this purpose.

The dye remaining unadsorbed should be washed away immediately after adsorption. Washing is conveniently carried out in a wet washing tank with an organic solvent, such as a polar solvent (e.g., acetonitrile) or an alcohol. If desired, the surface of the semiconductor particles can be treated with an amine after dye adsorption. Preferred amines include pyridine, 4-t-butylpyridine, and polyvinylpyridine. The amine can be used as such where it is liquid, or as dissolved in an organic solvent.

(C) Charge Transporting Layer

The charge transporting layer is a layer comprising a charge transporting material which supplies electrons to the dye molecules in their oxidized state. The charge transporting material which can be used in the invention typically includes (1) ion transporting materials, such as a solution of a redox ion system in an organic solvent (i.e., an electrolytic solution), a gel electrolyte comprising a polymer matrix impregnated with a solution of a redox ion system in an organic solvent, and a molten salt containing a redox ion system. A solid electrolyte is also useful. In place of the ion transporting materials, (2) solid materials in which carriers migrate to serve for electric conduction, i.e., electron transporting materials or (positive) hole transporting materials, can also be used. The former and the latter types of charge transporting materials can be used in combination.

(1) Molten Salt Electrolyte

A molten salt electrolyte is preferred for securing both photoelectric efficiency and durability. Known iodine salts described, e.g., in WO 95/18456, JP-A-8-259543, and Denki Kagaku, vol. 65, No. 11, p. 923 (1997), such as pyridinium iodides, imidazolium iodides, and triazolium iodides, can be used.

Molten salts which can be used preferably include those represented by the following formulae (Y-a), (Y-b), and (Y-c):

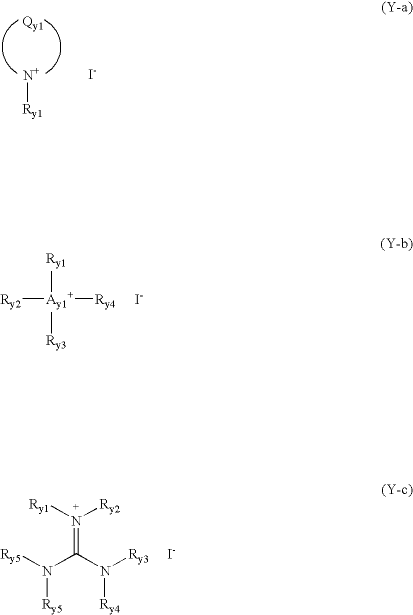

In formula (Y-a), Q_{y1} represents an atomic group forming a 5- or 6-membered aromatic cation together with the nitrogen atom. Q_{y1} is preferably made up of at least one atom selected from the group consisting of carbon, hydrogen, nitrogen, oxygen, and sulfur. The 5-membered ring completed by Q_{y1} is preferably an oxazole ring, a thiazole ring, an imidazole ring, a pyrazole ring, an isoxazole ring, a thiadiazole ring, an oxadiazole ring or a triazole ring, still preferably an oxazole ring, a thiazole ring or an imidazole ring, particularly preferably an oxazole ring or an imidazole ring. The 6-membered ring completed by Q_{y1} is preferably a pyridine ring, a pyrimidine ring, a pyridazine ring, a pyrazine ring or a triazine ring, with a pyridine ring being still preferred.

In formula (Y-b), A_{y1} represents a nitrogen atom or a phosphorus atom.

In formulae (Y-a), (Y-b) and (Y-c), R_{y1}, R_{y2}, R_{y3}, R_{y4}, R_{y5}, and R_{y6} each independently represent a substituted or unsubstituted alkyl group (preferably a straight-chain, branched or cyclic alkyl group having 1 to 24 carbon atoms, such as methyl, ethyl, propyl, isopropyl, pentyl, hexyl, octyl, 2-ethylhexyl, t-octyl, decyl, dodecyl, tetradecyl, 2-hexyldecyl, octadecyl, cyclohexyl, or cyclopentyl) or a substituted or unsubstituted alkenyl group (preferably a straight-chain or branched alkenyl group having 2 to 24 carbon atoms, such as vinyl or allyl). R_{y1}, R_{y2}, R_{y3}, R_{y4}, R_{y5}, and R_{y6} each preferably represent an alkyl group having 2 to 18 carbon atoms or an alkenyl group having 2 to 18 carbon atoms, particularly an alkyl group having 2 to 6 carbon atoms.

In formula (Y-b), two or more of R_{y1}, R_{y2}, R_{y3}, and R_{y4} may be taken together to form a non-aromatic ring containing A_{y1}. In formula (Y-c), two or more of R_{y1}, R_{y2}, R_{y3}, R_{y4}, R_{y5}, and R_{y6} may be taken together to form a cyclic structure.

In formulae (Y-a), (Y-b), and (Y-c), Q_{y1}, R_{y1}, R_{y2}, R_{y3}, R_{y4}, R_{y5}, and R_{y6} may have a substituent (s). Suitable substituents include a halogen atom (e.g., F, Cl, Br or I), a cyano group, an alkoxy group (e.g., methoxy or ethoxy), an aryloxy group (e.g., phenoxy), an alkylthio group (e.g., methylthio or ethylthio), an alkoxycarbonyl group (ethoxycarbonyl), a carbonic ester group (e.g., ethoxycarbonyloxy), an acyl group (e.g., acetyl, propionyl or benzoyl), a sulfonyl group (e.g., methanesulfonyl or benzenesulfonyl), an acyloxy group (e.g., acetoxy or benzoyloxy), a sulfonyloxy group (e.g., methanesulfonyloxy or toluenesulfonyloxy), a phosphonyl group (e.g., diethylphosphonyl), an amido group (e.g., acetylamino or benzoylamino), a carbamoyl group (e.g., N,N-dimethylcarbamoyl), an alkyl group (methyl, ethyl, propyl, isopropyl, cyclopropyl, butyl, 2-carboxyethyl or benzyl), an aryl group (e.g., phenyl or toluyl), a heterocyclic group (e.g., pyridyl, imidazolyl or furanyl), and an alkenyl group (e.g., vinyl or 1-propenyl).

The compounds represented by formulae (Y-a), (Y-b) or (Y-c) may form dimers or polymers at Q_{y1}, R_{y1}, R_{y2}, R_{y3}, R_{y4}, R_{y5} or R_{y6}.

These molten salts may be used either individually or as a mixture of two or more thereof or in combination with other molten salts having the above-described structures in which the iodide anion is replaced with other anions, preferably other halide ions (e.g., Cl⁻ and Br⁻), NSC⁻, BF₄⁻, PF₆⁻, ClO₄⁻, (CF₃SO₂)₂N⁻, (CF₃CF₂SO₂)₂N⁻, CF₃SO₃⁻, CF₃COO⁻, Ph₄B⁻, and (CF₃SO₂)₃C⁻, particularly (CF₃SO₂)₂N⁻ or BF₄⁻. Other iodine salts, such as LiI, can also be added.

Specific examples of molten salts which are preferably used in the invention are shown below for illustrative purposes only but not for limitation.

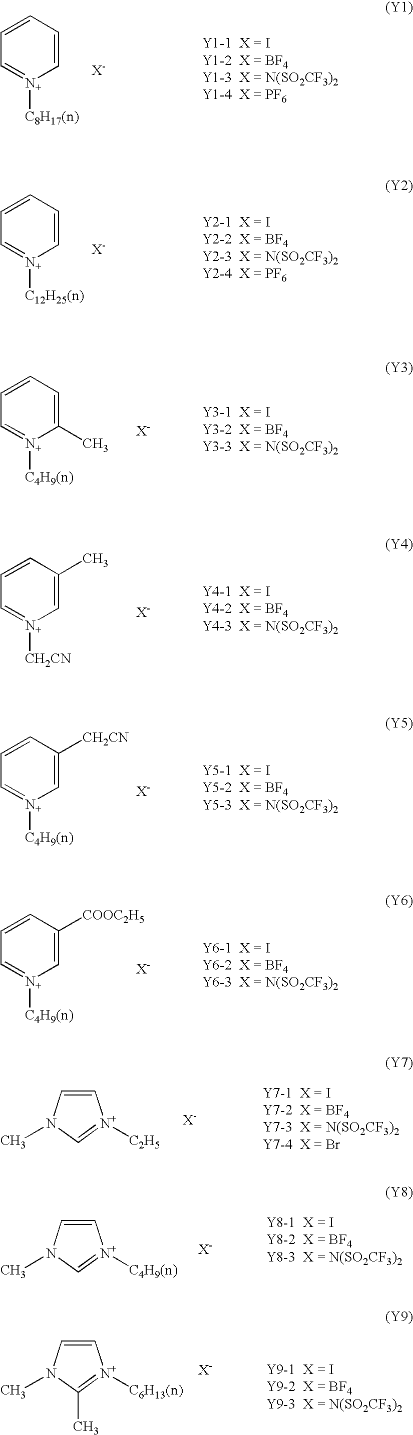

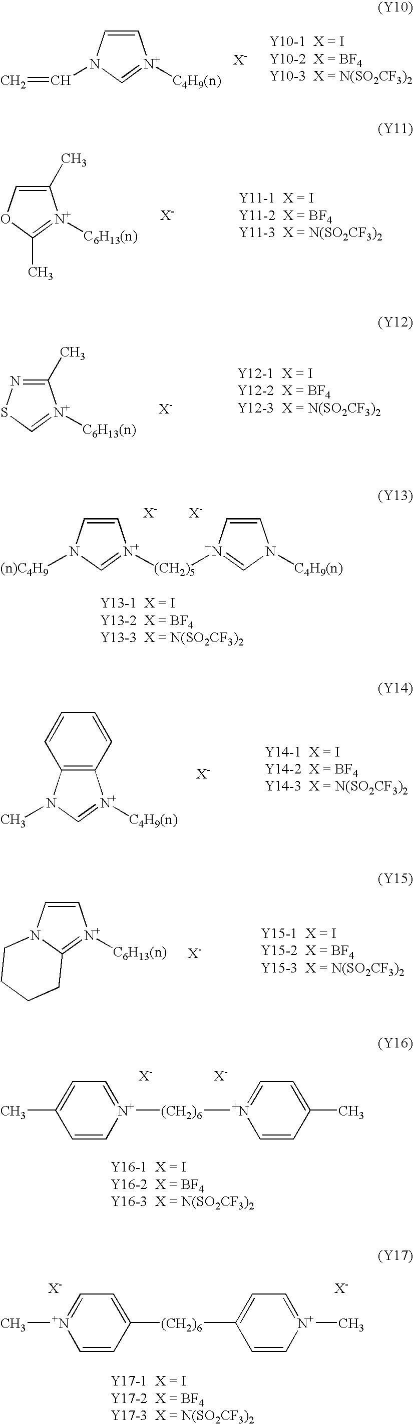

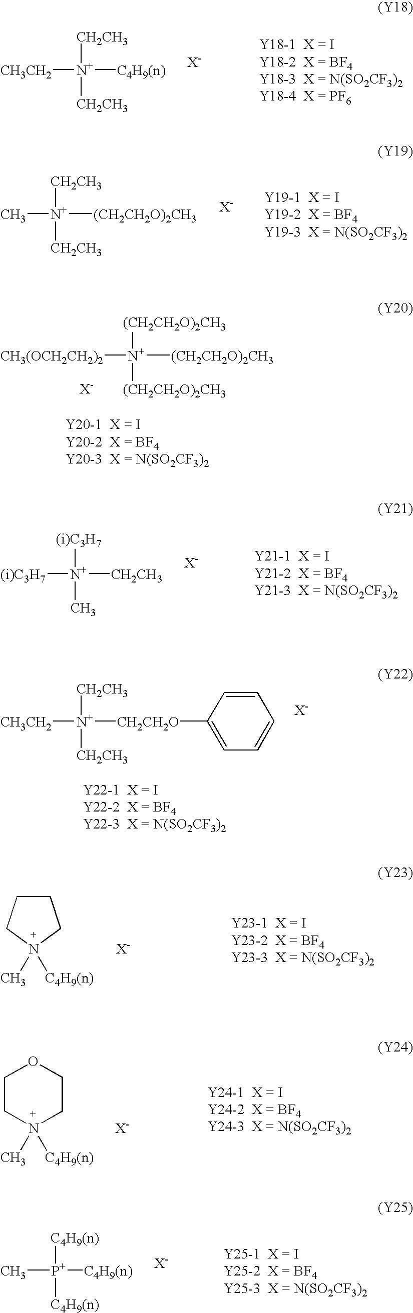

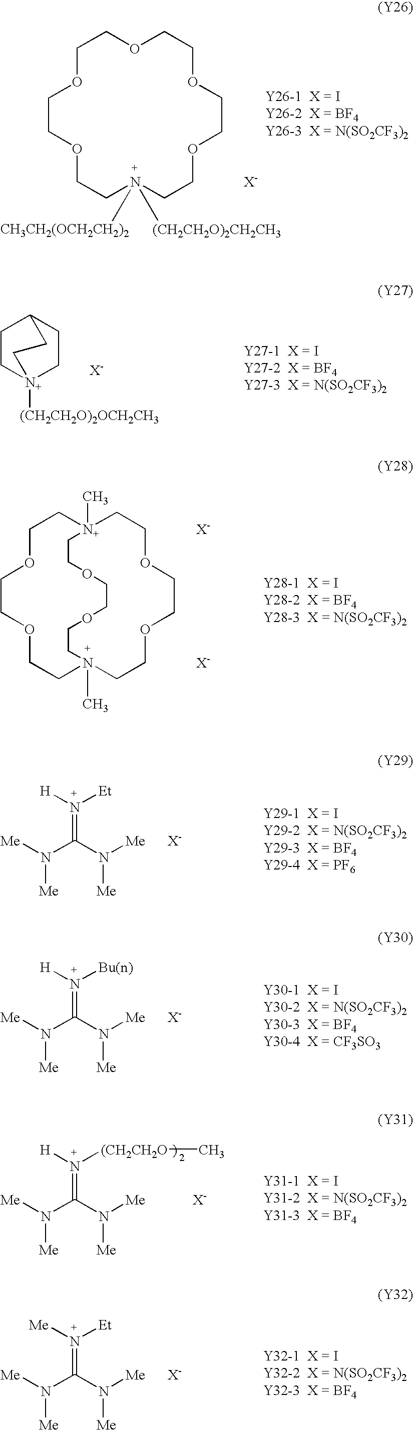

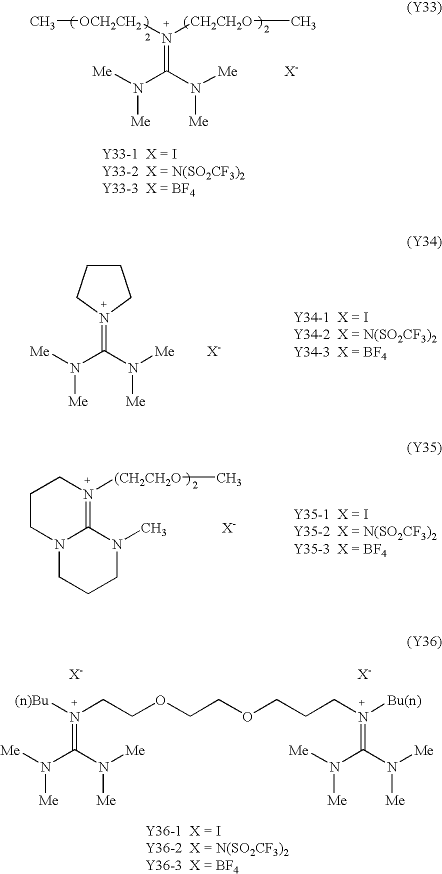

Of the above-recited molten salts, those which are in a molten state at ambient temperature are preferred. While the molten salt can be used with or without the solvent hereinafter described, it is preferred that the molten salt be used without a solvent. When used with a solvent, the molten salt is preferably used in an amount of at least 50% by weight, particularly 90% by weight or more, based on the total electrolyte composition, and 50% by weight or more of the molten salt is preferably an iodine salt.

It is preferable to add iodine to the electrolyte composition. Iodine is preferably added in an amount of 0.1 to 20% by weight, particularly 0.5 to 5% by weight, based on the total electrolyte composition.

(2) Electrolytic Solution

Where an electrolytic solution is used to form a charge transporting layer, it preferably comprises an electrolyte, a solvent, and additives. Preferred electrolytes include combinations of I₂ and iodides (for example, metal iodides, such as LiI, NaI, KI, CsI or CaI₂, and an iodine salt of quaternary ammonium compounds, such as a tetraalkylammonium iodide, pyridinium iodide and imidazolium iodide); combinations of Br₂ and bromides (for example, metal bromides, such as LiBr, NaBr, KBr, CsBr or CaBr₂, and a bromine salt of quaternary ammonium compounds, such as a tetraalkylammonium bromide or pyridinium bromide); metal complexes, such as a ferrocyananate-ferricyanate system or a ferrocene-ferricinium ion system; sulfur compounds, such as poly(sodium sulfite) and an alkylthiol-alkyl disulfide; viologen dyes; hydroquinone-quinone; and the like. Preferred of them are combinations of I₂ and an iodine salt of a quaternary ammonium compound, such as pyridinium iodide or imidazolium iodide. These electrolytes can be used either individually or as a mixture thereof.

A preferred electrolyte concentration is 0.1 to 15 M, particularly 0.2 to 10 M. Where iodine is added to the electrolyte, it is added preferably in a concentration of 0.01 to 0.5 M.

The solvent used to dissolve the electrolyte is preferably selected from those having a low viscosity to improve ion mobility or those having a high dielectric constant to improve an effective carrier concentration, thereby to develop excellent ionic conduction. Such solvents include carbonate compounds, such as ethylene carbonate and propylene carbonate; heterocyclic compounds, such as 3-methyl-2-oxazolidinone; ether compounds, such as dioxane and diethyl ether; acyclic ethers, such as ethylene glycol dialkyl ethers, propylene glycol dialkyl ethers, polyethylene glycol dialkyl ethers, and polypropylene glycol dialkyl ethers; alcohols, such as methanol, ethanol, ethylene glycol monoalkyl ethers, propylene glycol monoalkyl ethers, polyethylene glycol monoalkyl ethers, and polypropylene glycol monoalkyl ethers; polyhydric alcohols, such as ethylene glycol, propylene glycol, polyethylene glycol, polypropylene glycol, and glycerol; nitrile compounds, such as acetonitrile, glutaronitrile, methoxyacetonitrile, propionitrile, and benzonitrile; aprotic polar solvents, such as dimethyl sulfoxide and sulfolane; and water.

The electrolyte can contain a basic compound, such as t-butylpyridine, 2-picoline, and 2,6-lutidine, as disclosed in J. Am. Ceram. Soc., vol. 80, No. 12, pp. 3157-3171 (1997). A preferred concentration of the basic compound, if added, is 0.05 to 2 M.

(3) Gel Electrolyte

A liquid electrolyte can be solidified into gel by addition of a polymer, addition of an oil gelling agent, polymerization of a polyfunctional monomer, crosslinking of a polymer, or a like technique. Polymers which can be added to cause the electrolyte to gel include the compounds described in J. R. MacCallum and C. A. Vincent, Elsevier Applied Science, “Polymer Electrolyte Reviews-1 and 2”. Polyacrylonitrile and polyvinylidene fluoride are particularly preferred. Oil gelling agents which can be added to cause the electrolyte to gel include the compounds disclosed in J. Chem. Soc., Japan Ind. Chem. Soc., vol. 46, p. 779 (1943), J. Am. Chem. Soc., vol. 111, p. 5542 (1989), J. Chem. Soc., Chem. Commun., p. 390 (1993), Angew. Chem. Int. Ed. Eng., vol. 35, p. 1949 (1996), Chem. Lett., p. 885 (1996), and J. Chem. Soc., Chem. Commun., p. 545 (1997). In particular, compounds having an amido structure in the molecule are preferred.

Where the electrolyte is made to gel by crosslinking reaction of a polymer, it is desirable to use a polymer having a crosslinkable reactive group in combination with a crosslinking agent. The crosslinkable reactive group preferably includes nitrogen-containing heterocyclic groups, such as a pyridine ring, an imidazole ring, a thiazole ring, an oxazole ring, a triazole ring, a morpholine ring, a piperidine ring, and a piperazine ring. Preferred crosslinking agents include bi- or polyfunctional reagents capable of nucleophilic reaction with a nitrogen atom, such as alkyl halides, aralkyl halides, sulfonic esters, acid anhydrides, acid chlorides, and isocyanate compounds.

(4) Hole Transporting Material

In the present invention, an organic and/or an inorganic hole transporting material can be used in place of the ion conductive electrolyte.

(a) Organic Hole Transporting Material

Useful organic hole transporting materials include aromatic amines, such as those described in J. Hagen et al., Synthetic Metal, vol. 89, pp. 215-220 (1997), Nature, vol. 395, pp. 583-585 (Oct. 8, 1998), WO97/10617, JP-A-59-194393, JP-A-5-234681, U.S. Pat. No. 4,923,774, JP-A-4-308688, U.S. Pat. No. 4,764,625, JP-A-3-269084, JP-A-4-129271, JP-A-4-175395, JP-A-4-264189, JP-A-4-290851, JP-A-4-364153, JP-A-5-25473, JP-A-5-239455, JP-A-5-320634, JP-A-6-1972, JP-A-7-138562, JP-A-7-252474, JP-A-11-144773; and triphenylene derivatives described in JP-A-11-176489.

Also useful are conductive polymers, such as oligothiophene compounds described in Adv. Mater., vol. 9, No. 7, p. 557 (1997), Angew., Chem. Int. Ed. Eng., vol. 34, No. 3, pp. 303-307 (1995), JACS, vol. 120, No. 4, pp. 664-672 (1998); polypyrrole compounds described in K. Murakoshi et al., Chem. Lett., p. 471 (1997); and polyacetylene and derivatives thereof, poly(p-phenylene) and derivatives thereof, poly(p-phenylenevinylene) and derivatives thereof, polythienylenevinylene and derivatives thereof, polythiophene and derivatives thereof, polyaniline and derivatives thereof, and polytoluidine and derivatives thereof described in H. S. Nalwa (ed.), Handbook of Conductive Molecules and Polymers, vols. 1-4 (1997).

As taught in Nature, vol. 395, pp. 583-585 (Oct. 8, 1998), a compound containing a cationic radical, such as tris(4-bromophenyl)aluminum hexachloroantimonate, can be added to the organic hole transporting material so as to control the dopant level, or a salt such as Li[(CF₃SO₂)₂N] can be added to control the oxide semiconductor surface potential (i.e., compensation of a space charge layer).

(b) Inorganic Hole Transporting Material

The inorganic hole transporting material preferably comprises a p-type inorganic compound semiconductor. It is preferred for the p-type inorganic compound semiconductor to have a band gap of 2 eV or more, particularly 2.5 eV or more. In order to reduce the dye holes, it is necessary for the p-type inorganic compound semiconductor to have an ionization potential smaller than that of the dye-sensitized electrode. While a preferred range of the ionization potential of the p-type inorganic compound semiconductor used in the hole transporting layer varies depending on the sensitizing dye used, it is usually 4.5 to 5.5 eV, particularly 4.7 to 5.3 eV. The p-type inorganic compound semiconductor is preferably a compound semiconductor containing monovalent copper. Compound semiconductors containing monovalent copper include CuI, CuSCN, CuInSe₂, Cu(In,Ga)Se₂, CuGaSe₂, Cu₂O, CuS, CuGaS₂, CuInS₂, and CuAlSe₂, with CuI and CuSCN being preferred. CuI is the most preferred. Additionally, GaP, NiO, CoO, FeO, Bi₂O₃, MoO₂, Cr₂O₃, etc. are useful as a p-type inorganic compound semiconductor.

The charge transporting layer comprising a p-type inorganic compound semiconductor preferably has a hole mobility of 10⁻⁴ cm²/V·sec to 10⁴ cm²/V·sec., particularly 10⁻³ cm²/V·sec to 10³ cm²/V·sec. The charge transporting layer preferably has an electrical conductivity of 10⁻⁸ S/cm to 10² S/cm, particularly 10⁻⁶ S/cm to 10 S/cm.

(5) Formation of Charge Transporting Layer

There are two conceivable methods of forming a charge transporting layer. One comprises adhering a counterelectrode to the dye-sensitized semiconductor layer and penetrating a liquid charge transporting material into the gap therebetween. The other comprises forming a charge transporting layer on the dye-sensitized semiconductor layer and then providing a counterelectrode thereon. The former method can be effected by an ambient pressure process which makes use of capillarity by, for example, soaking or a vacuum process in which a gas phase of the gap is displaced with a liquid phase under reduced pressure.

The latter method embraces various embodiments. Where the charge transporting layer is of a wet system, a counterelectrode is provided thereon while the layer is wet, and the edges call for a leakproof measure. In the case of a gel electrolyte, a wet electrolyte as applied may be solidified into gel by, for example, polymerization. In this case, the gel electrolyte can be dried and fixed before a counterelectrode is provided. A wet organic hole-transporting material or a gel electrolyte as well as an electrolytic solution can be applied in the same manner as for the formation of the particulate semiconductor layer or for dye adsorption.

A solid electrolyte or a solid hole-transporting material can be applied by dry film forming techniques, such as vacuum evaporation or CVD, and then a counterelectrode is provided thereon. The organic hole transporting material can be introduced into the inside of the electrode by vacuum evaporation, casting, coating, spin coating, dipping, electrolytic polymerization, photo-electrolytic polymerization, or a like technique. The inorganic hole transporting material can also be introduced into the inside of the electrode by casting, coating, spin coating, dipping, electrolytic plating, or a like technique.

(D) Counterelectrode

Similarly to the above-described conductive substrate, the counterelectrode may be a single layer made up of an electrically conducting agent (counterelectrode conductive layer) or a combination of the counterelectrode conductive layer and a supporting base. Conducting agents of choice for the counterelectrode include metals (e.g., platinum, gold, silver, copper, aluminum, magnesium, and indium), carbon, and conductive metal oxides (e.g., indium-tin complex oxide and fluorine-doped tin oxide). Preferred of these conducting agents are platinum, gold, silver, copper, aluminum and magnesium. Suitable supporting bases include a glass or plastic base, on which the above-described conducting agent is applied or deposited.

While not limiting, the counterelectrode conductive layer preferably has a thickness of 3 nm to 10 μm. In particular, a metallic counterelectrode conductive layer preferably has a thickness of 5 μm or smaller, particularly 10 nm to 3 μm. The surface resistivity of the counterelectrode is preferably as low as possible. A preferred surface resistivity of the counterelectrode is 50 Ω/square or lower, particularly 20 Ω/square or lower.

Since light should enter the photoelectric conversion device from either one or both of the conductive substrate and the counterelectrode, at least one of the conductive substrate and the counterelectrode must be substantially transparent so that incident light can pass therethrough and reach the photosensitive layer. It is preferred for power generation efficiency that the conductive substrate be transparent so that light may be incident upon this side. In this case, it is a preferred embodiment that the counterelectrode has light reflecting properties. A glass or plastic base having a metal or conductive oxide deposit layer or a metallic thin film can be used as a reflective counterelectrode.

The counterelectrode is formed either by coating the charge transporting layer with a conducting material by application, plating or vacuum deposition (PVD or CVD) or by sticking a base having a conductive layer to the charge transporting layer with its conductive layer inside. It is preferred, as with the case of the conductive substrate, to use metal leads for decreasing the resistance particularly where the counterelectrode is transparent. The above-described particulars as to the material of metal leads, method for making metal leads, reduction in incident light quantity due to metal leads apply to the counterelectrode.

(E) Other Layers

It is a preferred embodiment to previously provide a dense and thin semiconductor layer on the conductive substrate as an undercoat to prevent a short circuit between the counterelectrode and the conductive substrate. To provide an undercoat is particularly effective in using an electron transporting material or a hole transporting material as a charge transporting material. The undercoat preferably comprises an oxide semiconductor, such as TiO₂, SnO₂, Fe₂O₃, WO₃, ZnO, and Nb₂O₅. TiO₂ is still preferred. The undercoat can be formed by, for example, spray pyrolysis as described in Electrochimi. Acta, vol. 40, pp. 643-652 (1995) or sputtering. A preferred thickness of the undercoat is 5 to 1000 nm, particularly 10 to 500 nm.

If necessary, additional functional layers, such as a protective layer and an antireflection layer, can be formed on the inner side or the outer side of the conductive substrate of the work electrode and/or the counterelectrode. Depending on the material, these functional layers may be provided by vacuum evaporation or press bonding.

(F) Internal Structure of Photoelectric Conversion Device

As described above, the photoelectric conversion device can have a variety of internal structures in conformity with the end use. Conceivable forms are roughly divided into two types; structures which receive light from both sides and those which receive light from one side. Internal structures of photoelectric conversion devices that are suitably applied to the present invention are shown in FIGS. 2 through 9.

FIG. 2 is a structure made up of a pair of transparent conductive layers (a transparent conductive layer 10a and a transparent counterelectrode conductive layer 40a) having sandwiched therebetween a photosensitive layer 20 and a charge transporting layer 30, which allows light to enter from its both sides.

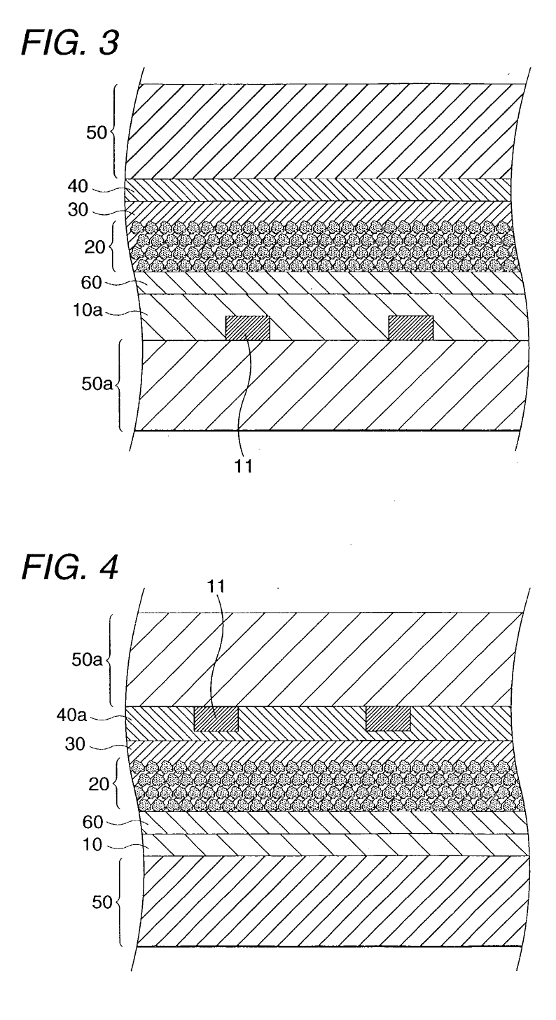

FIG. 3 is a structure having, in the order described, a transparent base 50a, a metal lead 11 which is provided in parts, a transparent conductive layer 10a, an undercoat 60, a photosensitive layer 20, a charge transporting layer 30, a counterelectrode conductive layer 40, and a base 50, which allows light to enter from its conductive layer side.

FIG. 4 shows a structure having, in the order described, a base 50, a conductive layer 10, an undercoat 60, a photosensitive layer 20, a charge transporting layer 30, a transparent counterelectrode conductive layer 40a, and a transparent base 50a partially having thereon a metal lead 11 with the metal lead 11 inside, which allows light to enter from the counterelectrode side.

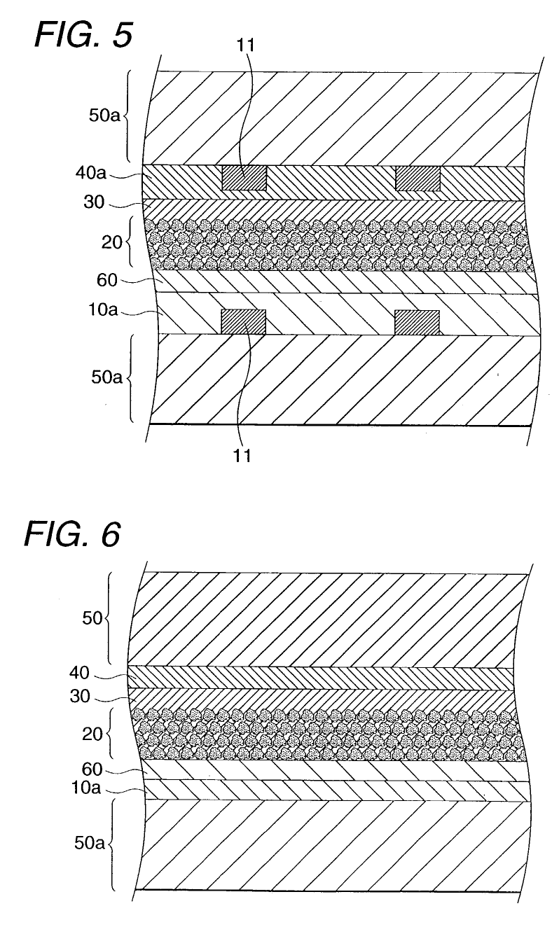

FIG. 5 is a structure having, in the order described, a transparent base 50a, a metal lead 11 which is provided in parts, a transparent conductive layer 10a, an undercoat 60, a photosensitive layer 20, a charge transporting layer 30, a transparent counterelectrode conductive layer 40a, and another transparent base 50a having thereon a metal lead 11 in parts with the metal lead 11 inside, which allows light to enter from both sides thereof.

FIG. 6 depicts a structure having, in the order described, a transparent base 50a, a transparent conductive layer 10a, an undercoat 60, a photosensitive layer 20, a charge transporting layer 30, a counterelectrode conductive layer 40, and a base 50, which allows light to enter from its conductive layer side.

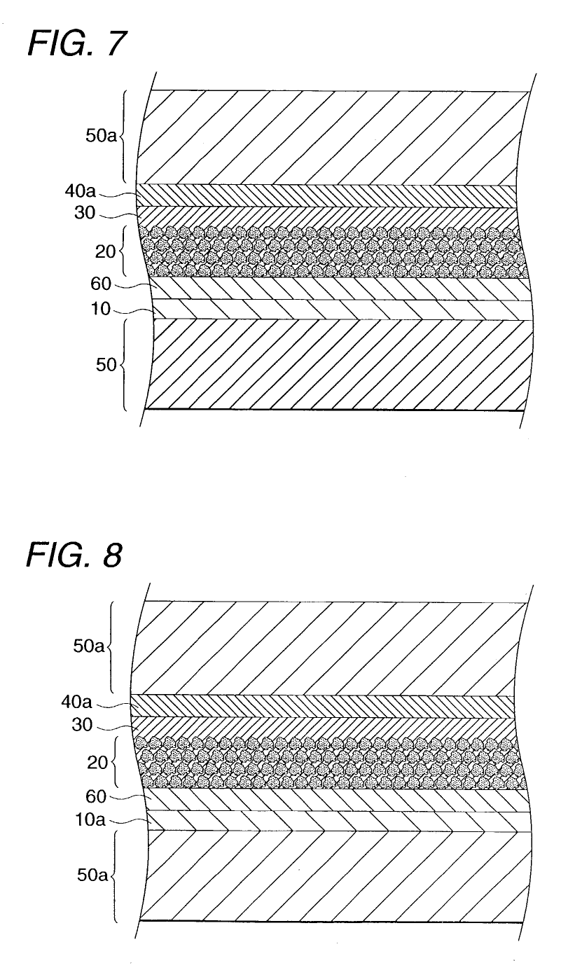

FIG. 7 illustrates a structure having, in the order described, a base 50, a conductive layer 10, an undercoat 60, a photosensitive layer 20, a charge transporting layer 30, a transparent counterelectrode conductive layer 40a, and a transparent base 50a, which allows light to enter from the counterelectrode side.

FIG. 8 shows a structure having, in the order described, a transparent base 50a, a transparent conductive layer 10a, an undercoat 60, a photosensitive layer 20, a charge transporting layer 30, a transparent counterelectrode conductive layer 40a, and a transparent base 50a, which allows light to enter from its both sides.

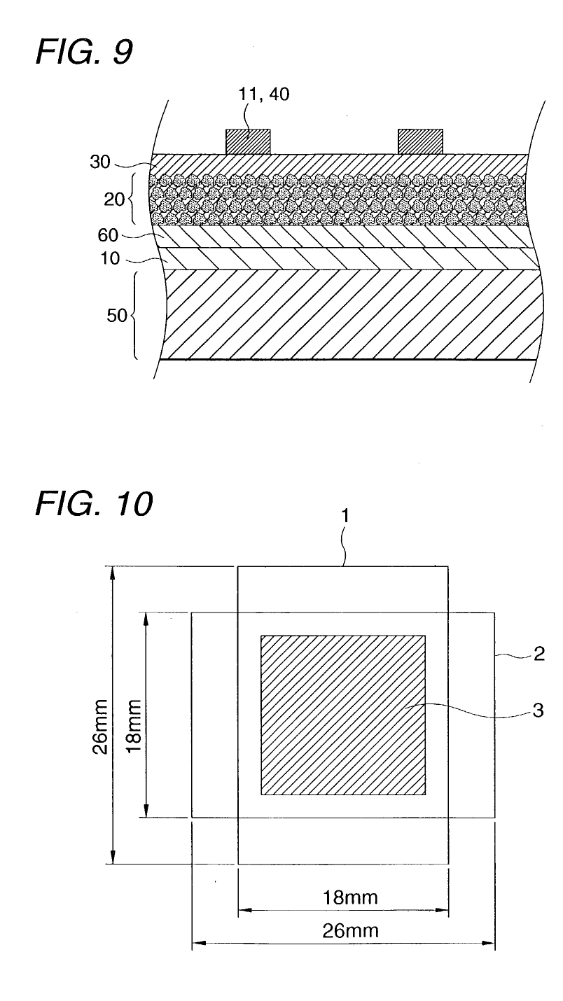

FIG. 9 is a structure having, in the order described, a base 50, a conductive layer 10, an undercoat 60, a photosensitive layer 20, a solid charge transporting layer 30, and a counterelectrode conductive layer 40 or a metal lead 11 provided in parts, which allows light to enter from the counterelectrode side.

[II] Photo Cell

The photo cell of the present invention is a practical application of the above-described photoelectric conversion device, in which the photoelectric conversion device is designed to work in an external circuit to which it is connected. of photo cells those in which the charge transporting material mainly comprises ion transporting material are called photo-electrochemical cells, and those chiefly designed for power generation with sunlight are named solar cells. A photo cell preferably has its sides sealed with a polymer, an adhesive, etc. to prevent deterioration by oxidation or volatilization of the volatile matter contained therein. The external circuit connected to the conductive substrate and the counterelectrode via the respective leads is well known. The solar cell to which the photoelectric conversion device of the invention is applied basically has the same internal structure as the above-described photoelectric conversion device.

The dye-sensitized solar cell according to the present invention basically has the same module structure as conventional solar cell modules. It generally comprises cells built up on a metallic, ceramic or like substrate and covered with a filling resin or protective glass so that light can enter on the side opposite to the substrate. Where the substrate, on which the cells are provided, is made of a transparent material such as tempered glass, the cells can take in light from the side of the transparent substrate. Known module structures include a superstraight type, a substraight type or potting type or a substrate-integrated type used in amorphous silicon solar cells. A suitable module structure can be chosen appropriately according to the end use, the place of use, or the environment in which it is to be used. For the details, reference can be made to Japanese Patent Application No. 8457/99.

### EXAMPLE

The present invention will now be illustrated in greater detail with reference to Examples, but it should be noted that the invention is not limited thereto. Unless otherwise noted, all the percents are by weight.

### Example 1

1-1) Preparation of Titanium Dioxide Dispersion-1

Titanium tetraisopropoxide (142.1 g) and 149.2 g of triethanolamine were mixed in a dry box at room temperature. After being allowed to stand for 2 hours in the dry box, the mixture was diluted with distilled water to make 1000 ml. A 100 ml portion of the resulting mixture was mixed with distilled water to which 2.35 ml of acetic acid had been added to make 100 ml. The mixture (200 ml) was heated in a closed container at 100° C. for 24 hours into a white gel. The temperature was raised to 140° C., at which the gel was further heated for 72 hours. After cooling to room temperature, the supernatant liquor was removed to obtain a pale reddish brown precipitate. The wet precipitate weighed 33 g. To the precipitate was added 1.0 g of polyethylene glycol having a molecular weight of 500,000, and the mixture was kneaded in a kneading machine for 20 minutes to prepare a titanium dioxide dispersion having a concentration of 12% (designated TiO₂ dispersion-1). TiO₂ dispersion-1 had an average particle size of about 16 nm and contained particles of 10 nm and smaller.

1-2) Preparation of TiO₂ Dispersion-2 (Containing Precursor)

To 4.5 ml of titanium tetraisopropoxide was added 25 ml of a 1 mol/l hydrochloric acid solution, and the mixture was stirred at room temperature. After 1 to 3 hour stirring, a 4 ml portion of the mixture was added to 15.5 g of TiO₂ dispersion-1 to obtain TiO₂ dispersion-2, which was used in the subsequent step immediately after mixing. The solid content of the precursor in TiO₂ dispersion-2 was approximately 1/24 based on the weight of TiO₂ particles.

2) Preparation of Dye-sensitized TiO₂ Electrode

A transparent conductive glass sheet having an F-doped tin oxide coat (available from Nippon Sheet Glass Co., Ltd.; surface resistivity: about 10 Ω/square) was used as a conductive substrate. TiO₂ dispersion-1 or -2 prepared in (1) above was applied on the conductive side of the substrate and treated under the conditions described below to prepare a porous semiconductor electrode comprising metal oxide particles. The coating weight and thickness of the TiO₂ layer thus formed were about 9.0 g/m² and about 6 μm, respectively. The amount of the dye adsorbed is shown in Table 1 below. The method of determining the adsorbed dye will be described later.

2-1) Preparation of Electrode A (Comparison)

Dispersion-1 was applied on the substrate to a thickness of 100 μm with a doctor blade, dried at 25° C. for 40 minutes, and fired in an electric muffle furnace (Model FP-32, manufactured by Yamato Kagaku) at 350° C. for 30 minutes. After cooling, the electrode was heated in an ethanolic solution of 3×10⁻⁴ mol/l of dye R-1 under reflux for 3 minutes. The resulting electrode was designated electrode A.

2-2) Preparation of Electrode B (Invention)

Dispersion-2 was applied on the substrate to a thickness of 100 μm with a doctor blade, dried at 25° C. for 40 minutes, and irradiated with ultraviolet light having a wavelength of 400 nm or shorter emitted from a xenon lamp for 30 minutes. The electrode was heated in an ethanolic solution of 3×10⁻⁴ mol/l of dye R-1 under reflux for 3 minutes. The resulting electrode was designated electrode B.

2-3) Preparation of Electrode C (Invention)

Dispersion-1 was applied on the substrate to a thickness of 100 μm with a doctor blade. After drying at 25° C. for 40 minutes, the electrode was placed on a hot plate at 150° C. and irradiated with ultraviolet light having a wavelength of 400 nm or shorter and an intensity of 30 mW/cm² for 30 minutes while heating. Heating and irradiation were stopped at the same time, and the electrode was heated in an ethanolic solution of 3×10⁻⁴ mol/l of dye R-1 under reflux for 3 minutes. The resulting electrode was designated electrode C.

2-4) Preparation of Electrode D (Invention)

Dispersion-1 was applied on the substrate to a thickness of 100 μm with a doctor blade. After drying at 25° C. for 40 minutes, the electrode was placed on a hot plate at 150° C. under reduced pressure of 0.04 MPa. The electrode was then heated in an ethanolic solution of 3×10⁻⁴ mol/l of dye R-1 under reflux for 3 minutes. The resulting electrode was designated electrode D.

2-5) Preparation of Electrode E (Invention)

Dispersion-1 was applied on the substrate to a thickness of 100 μm with a doctor blade, dried at 25° C. for 40 minutes, and irradiated with infrared light in a far-infrared heating oven for 30 minutes. The electrode was then heated in an ethanolic solution of 3×10⁻⁴ mol/l of dye R-1 under reflux for 3 minutes. The resulting electrode was designated electrode E.

2-6) Preparation of Electrode F (Invention)

Dispersion-1 was applied on the substrate to a thickness of 100 μm with a doctor blade. After drying at 25° C. for 40 minutes, the electrode was placed on a hot plate at 150° C. and irradiated with ultraviolet light having a wavelength of 400 nm or shorter and an intensity of 30 mW/cm² for 30 minutes. After the UV irradiation was ceased, heating was further continued for an additional 15 minute period. The electrode was then heated in an ethanolic solution of 3×10⁻⁴ mol/l of dye R-1 under reflux for 3 minutes. The resulting electrode was designated electrode E.

2-7) Preparation of Electrode G (Invention)

Electrode G was prepared in the same manner as for electrode F, except for using dispersion-2 in place of dispersion-1.

3) Formation of Charge Transporting Layer and Photo Cell Assembly

Each of the electrodes prepared above was cut into a piece 18 mm wide and 26 mm long. The titanium dioxide layer on the peripheral portion of the substrate was removed to leave a 14 mm-side square in the central portion as a light-receiving area.

3-1) Formation of Ion Transporting Layer and Photo Cell Assembly

The TiO₂ electrode 1 and a platinum-deposited glass substrate 2 (glass base thickness: 1.1 mm; platinum deposit layer thickness: 1 μm) of the same size (18 mm by 26 mm) as a counterelectrode were superposed crosswise with the conductive sides facing each other so that the 4 mm wide margins on both shorter sides were exposed to serve as terminals as shown in FIG. 10, with a polyethylene frame spacer 3 (thickness: 10 μm) interposed therebetween.

The whole cell except the light-receiving area (TiO₂ layer) was sealed in an epoxy resin adhesive. A molten salt electrolyte consisting of compound 1, compound 2 and iodine in a weight ratio of 15:35:1 was made to penetrate into the gap between the electrodes at 80° C. by making use of capillarity from a small hole that had been made through a side of the frame spacer. The hole was stopped up with the same adhesive. The resulting photo cells were designated samples 101 to 107.

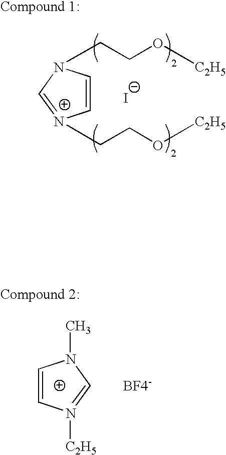

3-2) Formation of Hole Transporting Layer and Photo Cell Assembly

Electrode A, D or F, with the area other than the light-receiving area (TiO₂ layer) masked, was heated on a hot plate at 100° C. for 2 minutes. Then 0.2 ml of a 3.2% acetonitrile solution of 65 -CuI was slowly added on the TiO₂ layer over a period of 10 minutes while letting acetonitrile vaporize. After completion of the addition, the electrode was left to stand on the hot plate for 2 minutes to form a CuI layer as a hole transporting layer. The same platinum-deposited glass substrate as used in (3-1) was superposed thereon under pressure, and the whole cell except the light-receiving area was sealed in an epoxy resin adhesive to obtain photo cell samples 201 to 203.

4) Measurement of Photoelectric Conversion Efficiency

The photo cell was irradiated with pseudo-sunlight having an intensity of 100 mW/cm² which was created by cutting light from a 500 W xenon lamp (produced by Ushio Inc.) through a spectral filter (AM1.5 Filter available from Oriel). The generated electricity was recorded with a Keithley electrometer (Model SMU2400). The conversion efficiency (η, %) of the photo cell is shown in Table 1.

5) Measurement of Amount of Adsorbed Dye

After the measurement (4), each of samples 101 to 107 having an ion transporting layer was taken apart, and the electrolyte was washed off with acetonitrile. The adsorbed dye was extracted with an alkali solution and determined. The results obtained are shown in Table 1. The dye adsorbed by the hole transporting layer in samples 201 to 203 was unmeasurable on account of difficulty in extracting the dye.

TABLE 1

| | | | Absorbed | Conversion | |
|---|---|---|---|---|---|
| | Electrode | | Dye (×10⁴ | Efficiency | |
| Sample | (Treatment) | Carrier | mol/m²) | (%) | Remark |
| 101 | A (350° C.) | ion | 3.4 | 0.7 | comparison |
| 102 | B (UV + precursor) | ion | 5.1 | 2.4 | invention |
| 103 | C (UV + 150° C.) | ion | 7.0 | 2.7 | invention |
| 104 | D (vacuum + 250° C.) | ion | 6.7 | 1.7 | invention |
| 105 | E (IR) | ion | 6.4 | 1.4 | invention |
| 106 | F (UV + 150° C.) | ion | 8.2 | 3.0 | invention |
| 107 | G (UV + 150° C. + | ion | 8.0 | 3.2 | invention |
| | precursor) | | | | |
| 201 | A (350° C.) | hole | — | 0.3 | comparison |
| 202 | F (UV + 150° C.) | hole | — | 1.1 | invention |
| 203 | D (vacuum + 250° C.) | hole | — | 0.8 | invention |

It is seen from Table 1 that sample 101 (comparison) has a very small amount of the dye adsorbed and an extremely low conversion efficiency. Compared with this sample, samples 102 to 107 in which the electrode had been prepared by the specific treatment of the invention contain an increased amount of the dye and attain a higher photoelectric conversion efficiency. Of the treatments for preparing semiconductor electrodes, a combination of UV irradiation and heating (samples 103, 106 and 107) proves particularly excellent in both dye adsorption and conversion efficiency. On comparing sample 106 (UV irradiation and heating were ended at once) with sample 107 (the treatment ended with heating), it is recognized that both the amount of the dye adsorbed and the conversion efficiency are higher when the UV irradiation is followed by heating. This seems to be because UV irradiation makes the surface of titanium dioxide particles excessively hydrophilic, which is disadvantageous for dye adsorption, whereas heating makes the surface hydrophobic, which is advantageous for dye adsorption. A comparison between samples 106 and 107 reveals that the presence of the precursor brings about improvement in photoelectric conversion efficiency.

Similar tendencies are observed with photo cells having a hole transporting layer as a charge transporting layer (samples 201 to 203). Samples 202 and 203 having the electrode according to the invention achieve a higher photoelectric conversion efficiency than sample 201 (comparison) of which the electrode had been prepared by heating at 350° C. Compared with sample 203, sample 202 whose electrode had been treated by UV irradiation plus heating is superior.

### Example 2

Dye-sensitized semiconductor electrodes were prepared in the same manner as for electrodes A to G of Example 1, except for using a PET film having a conductive layer as a transparent conductive substrate. When the PET film was heated at 350° C. as in the preparation of electrode A, it was deformed and became useless in the subsequent photo cell assembly. The electrodes treated otherwise were successfully assembled into photo cells capable of photoelectric conversion.

The photoelectric conversion device according to the present invention is obtainable without involving high temperature heat-treatment. The photoelectric conversion device of the present invention achieves a high photoelectric conversion efficiency.

The entire disclosure of each and every foreign patent application from which the benefit of foreign priority has been claimed in the present application is incorporated herein by reference, as if fully set forth.

What is claimed is:

1. A method of making a photoelectric conversion device comprising a particulate semiconductor layer, wherein the particulate semiconductor layer is prepared by a method comprising a step of activating semiconductor particles, which step includes irradiating semiconductor particles with electromagnetic wave.

2. The method according to claim 1, wherein the electromagnetic wave is at least one selected from the group consisting of ultraviolet light, microwaves and infrared light.

3. The method according to claim 1, wherein the step of irradiating is conducted under a pressure of 0.05 MPa or lower.

4. The method according to claim 1, wherein the method further comprises a step of heating semiconductor particles at a temperature of 50° C. or higher and lower than 350° C.

5. The method according to claim 1, wherein the electromagnetic wave is ultraviolet light having a wavelength of 400 nm or shorter.

6. The method according to claim 1, wherein the electromagnetic wave is infrared light having a wavelength at which water molecules have an absorption.

7. The method according to claim 1, wherein the step of irradiating is conducted in the presence of a precursor of semiconductor particles.

8. The method according to claim 7, wherein a solid content of the precursor of semiconductor particles is 5/1000 to 1/5 based on the weight of the semiconductor particles.

9. The method according to claim 7, wherein the precursor of semiconductor particles is an alkoxide compound of a metal constituting the semiconductor, a halogen compound of the metal, or a compound obtained by completely or partially hydrolyzing a compound of the metal having a hydrolyzable group and completely or partially polymerizing the hydrolysis product.

10. The method according to claim 1, wherein the semiconductor particles constituting the particulate semiconductor layer comprise those having a particle size of 10 nm or greater and those having a particle size smaller than 10 nm.

11. The method according to claim 1, wherein the particulate semiconductor layer is sensitized with a dye.

12. The method according to claim 11, wherein the sensitization with a dye occurs after the irradiation.

13. The method according to claim 1, wherein the semiconductor particles constituting the particulate semiconductor layer are particles of titanium oxide, zinc oxide, tin oxide, tungsten oxide, niobium oxide, iron oxide, an alkaline earth metal titanate, an alkali metal titanate or a composite thereof.

14. The method according to claim 1, wherein the particulate semiconductor layer is provided on a substrate made of a polymer.

15. A method for making a photo cell comprising making a photoelectric conversion device according to the method of claim 1.

16. A method for making a photoelectric conversion device comprising a particulate semiconductor layer, wherein the particulate semiconductor layer is prepared by a method comprising a step of heating semiconductor particles at a temperature of 50° C. or higher and lower than 350° C. under a pressure of 0.05 MPa or lower.

17. The method according to claim 16, wherein the step of heating is conducted in the presence of a precursor of semiconductor particles.

18. The method according to claim 16, wherein the semiconductor particles constituting the particulate semiconductor layer comprise those having a particle size of 10 nm or greater and those having a particle size smaller than 10 nm.

19. The method according to claim 16, wherein the particulate semiconductor layer is provided on a substrate made of a polymer.

20. A method for making a photo cell comprising making a photoelectric conversion device according to the method of claim 16.

21. The method according to claim 16, wherein the semiconductor particles constituting the particulate semiconductor layer are particles of titanium oxide, zinc oxide, tin oxide, tungsten oxide, niobium oxide, iron oxide, an alkaline earth metal titanate, an alkali metal titanate or a composite thereof.
